(19) United States
(12) Patent Application Publication
(10) Pub. No.: US 2026/0304942 A1
(43) Pub. Date: Oct. 1, 2026

(54) INTEGRATED CIRCUITS WITH TUB CFET ARCHITECTURE FOR IMPROVED DEVICE SPACING

(71) Applicant: Intel Corporation, Santa Clara, CA (US)

(72) Inventors: Dan Lavric, Portland, OR (US); Glenn Glass, Portland, OR (US); Leonard Guler, Hillsboro, OR (US)

(73) Assignee: Intel Corporation, Santa Clara, CA (US)

(21) Appl. No.: 19/092,800

(22) Filed: Mar. 27, 2025

(51) Int. Cl. H10D 84/85; H10D 30/00; H10D 30/01; H10D 30/43; H10D 62/10; H10D 64/01; H10D 84/01

(52) U.S. Cl. CPC H10D 84/851; H10D 30/014; H10D 30/019; H10D 30/43; H10D 30/502; H10D 62/102; H10D 62/121; H10D 64/017; H10D 84/0172; H10D 84/0188; H10D 84/856

(57) ABSTRACT

Devices, integrated circuit structures, systems, and techniques are described herein related to a tub complementary field effect transistor architecture. Transistor structures each having first and second complementary and vertically aligned nanowires are separated by dielectric walls. A sacrificial material embedding one of the transistor structures is accessed and removed using a mask having an opening at least partially over the sacrificial material. At least a portion of a gate stack is formed on the exposed transistor structure, and such processing is repeated for any number of transistor structures.

### BACKGROUND

Higher performance, lower cost, increased miniaturization, and greater density of integrated circuits (ICs) are ongoing goals of the electronics industry. To maintain the pace of increasing transistor performance, for example, scaling of features in ICs continues to be a driving force. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity.

However, the need to scale features of ICs faces difficulties. For example, current subtractive patterning techniques for fabricating gate contacts cannot deliver suitable threshold voltage (e.g., flat VT) for advanced NMOS to PMOS spacing (N-P spacing). Such patterning faces difficulties of vertical profile fidelity, damage to nanoribbons, and others. Furthermore, subtractive patterning faces additional difficulties at NMOS to NMOS (N-N) and PMOS to PMOS (P-P) boundaries due to increased aspect ratios and due to N- and P-polarities being stacked on top of one another.

It is with respect to these and other considerations that the present improvements have been needed. Such improvements may become critical as the desire to deploy CFET ICs with increased densities and improved performance becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating exemplary methods for providing dielectric walls between adjacent CFET structures in tub gate architectures;

FIGS. 2, 3, 4, 5, 6, 7, 8, and 9 are cross-sectional side views of example CFET structures as particular fabrication operations of the methods of FIG. 1 are performed;

FIG. 10 is a cross-sectional side view of the integrated circuit structures of FIGS. 8 and 9 incorporated in a multi-layer integrated circuit device die;

FIG. 11 illustrates exemplary systems employing CFET integrated circuit structures with transistor structures separated by dielectric walls; and

FIG. 12 is a block diagram of a computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/-10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure.

Devices, integrated circuit die structures, apparatuses, systems, and techniques are described herein related to dielectric walls formed between gate stacks of stacked CFET transistor structures. The dielectric walls provide for self-aligned selective removal of sacrificial gates for processing the exposed transistor structures.

As discussed, current subtractive patterning techniques for fabricating gate contacts face difficulties including unsuitable threshold voltages across dies or wafers due to lithographic alignment while selective processing gates of the transistor structures. For example, edge placement error (EPE) misalignment during gate processing leads to undesirable VT variability in the resultant transistors. Other difficulties, including vertical profile fidelity, also arise during current subtractive patterning techniques. In embodiments discussed herein, adjacent CFET (complementary field effect transistor) structures each include a stack of nanowires or channel material layers of a first polarity or conductivity type vertically aligned with and separated from a stack of nanowires or channel material layers of a second polarity or conductivity type. For example, a stack of NMOS nanowires or channel material layers may be vertically over a stack of PMOS nanowires or channel material layers, or vice versa. For example, each CFET structure includes a stack of NMOS nanowires or channel material layers vertically aligned with a stack of PMOS nanowires or channel material layers. Adjacent ones of the CFET structures may be dedicated for different applications such as ultra-low VT (ULVT) and high VT (HVT), or others including low VT (LVT), standard VT (SVT), and so on.

Herein, the laterally adjacent CFET structures are separated by dielectric walls (which may be characterized as pixel walls) that extend vertically across the stacks of NMOS and PMOS nanowires or channel material layers. Such dielectric wall structures may form tub architectures or tub gate architectures. The dielectric walls may be embedded in sacrificial material (e.g., a sacrificial tungsten or other material). During access of particular ones of the CFET structures, a hardmask material is formed with an opening over the particular CFET structure. Ideally, the opening is perfectly aligned with the particular CFET structure. However, in real world processing, when the opening is not perfectly aligned, the dielectric walls provide EPE latitude such that the opening need only be within a portion of the dielectric material bounded by the dielectric walls. Therefore, the dielectric walls provide for a self-alignment structure for improved device performance and reduced VT variability.

In the context of CFET structures, the first exposed CFET structure (e.g., stacks of vertically aligned PMOS and NMOS nanowires or channel material layers) may be processed using any suitable technique or techniques known in the art. For example, the stacks of PMOS and NMOS nanowires or channel material layers may be fabricated with the same or different dielectric or dipole material layers, the same or different work function metals, the same or different gate fill metals, and so on. Furthermore, the stacks of PMOS and NMOS nanowires or channel material layers may be contacted or gated separately or together. Similarly, the second or any subsequently exposed CFET structure (e.g., stacks of vertically aligned PMOS and NMOS nanowires or channel material layers) may be similarly processed with the same or different dielectric or dipole material layers, the same or different work function metals, the same or different gate fill metals, with the stacks of PMOS and NMOS nanowires or channel material layers contacted or gated separately or together. Therefore, the discussed techniques improve or maintain process flexibility while improving patterning fidelity and resultant device VT both across die and across wafer.

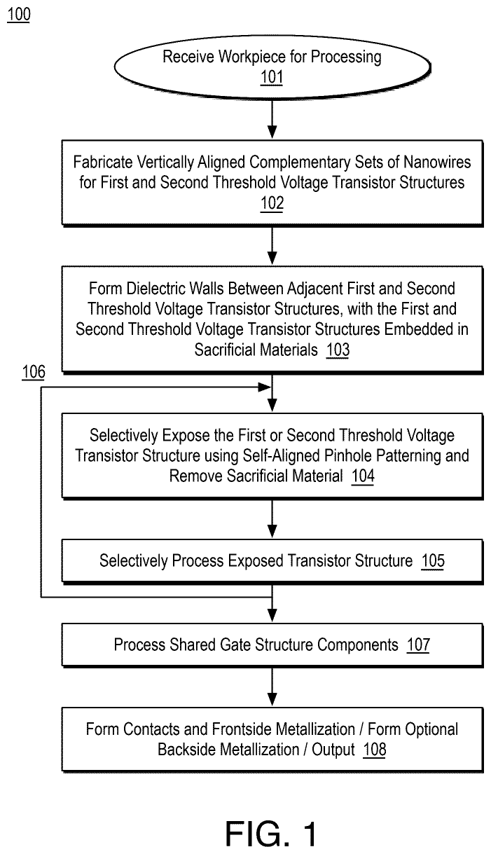

FIG. 1 is a flow diagram illustrating exemplary methods 100 for providing dielectric walls between adjacent CFET structures in tub gate architectures, arranged in accordance with at least some implementations of the present disclosure. For example, methods 100 may be implemented to fabricate any integrated circuit structures 800, 900, 1000 or any other integrated circuit structures discussed herein. In the illustrated implementation, methods 100 may include one or more operations as illustrated by operations 101-108. However, embodiments herein may include additional operations, certain operations being omitted, or operations being performed out of the order provided.

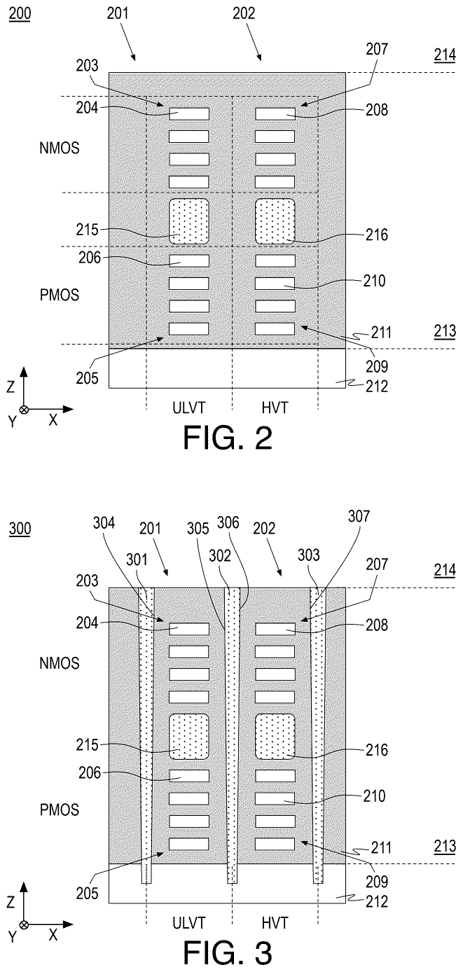

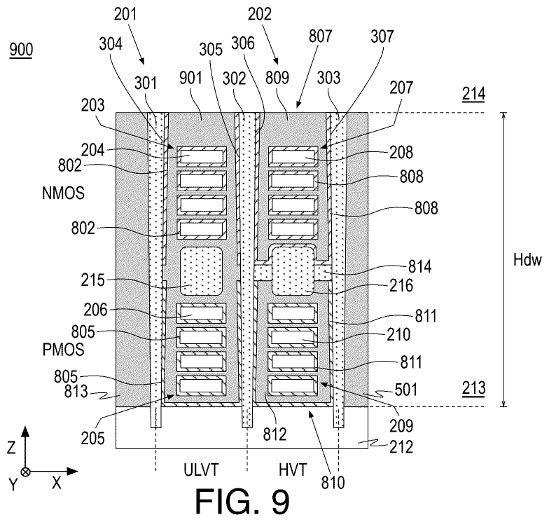

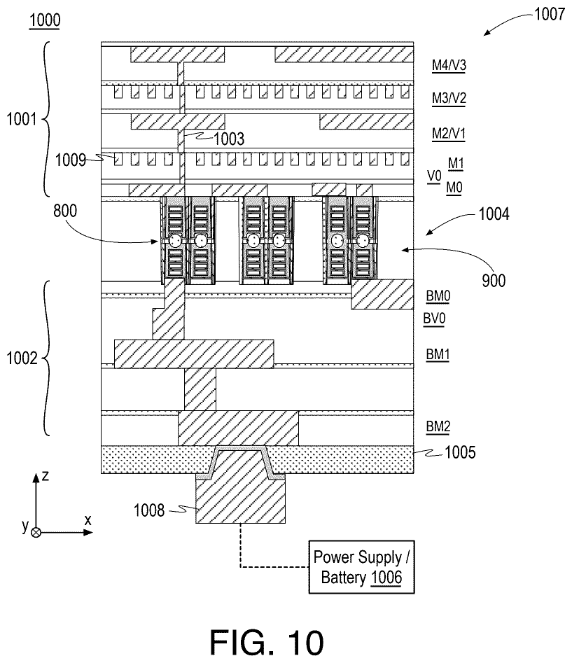

FIGS. 2, 3, 4, 5, 6, 7, 8, and 9 are cross-sectional side views of example CFET structures as particular fabrication operations of methods 100 are performed, arranged in accordance with at least some implementations of the present disclosure. FIG. 10 is a cross-sectional side view of the integrated circuit structures of FIGS. 8 and 9 incorporated in a multi-layer integrated circuit device die, arranged in accordance with at least some implementations of the present disclosure.

Processing begins at operation 101, where a workpiece such as a substrate is received for processing. The substrate may include any suitable substrate as discussed herein such as a silicon wafer or the like. In some embodiments, the substrate includes underlying devices or electrical interconnects. Processing continues at operation 102, where vertically aligned sets or stacks of complementary nanowires or channel material layers are fabricated for first and second threshold voltage CFET transistor structures.

For example, each CFET structure includes a first set of vertically aligned and separated nanowires and a second set of vertically aligned and separated nanowires that are also vertically aligned with the first set. The first set and the second set of nanowires or channel material layers are complementary such that one set is to use a first polarity or conductivity type (i.e., n-type conductors) and the other set is to use a second polarity or conductivity type (i.e., p-type conductors). The first and second sets may be the same materials, or they may be different. In some embodiments, the first and second sets of vertically aligned and separated nanowires are separated by a dielectric material layer.

Adjacent CFET structures (each having vertically aligned first and second sets of complementary nanowires) are to be laterally separate and to operate at different threshold voltages. Each CFET structure is to be separated by a vertical dielectric wall as discussed further herein, and each CFET structure may be defined in a tub or tub gate architecture.

The vertically aligned and separated nanowires may be formed using any suitable technique or techniques. In some embodiments, alternating layers of semiconductor material layers and sacrificial layers are formed over the workpiece or substrate, the alternating (or interleaved) layers of semiconductor material layers and sacrificial layers are patterned to form fin structures of the interleaved stack of semiconductor material layers and sacrificial layers, and dummy gate and spacer structures are formed. Components of the transistor structures such as sources and drains, spacers, etc. may then be formed and the semiconductor material layers may be released, as is known in the art.

The alternating layers of semiconductor material layers and sacrificial layers may be formed using any suitable technique or techniques such as epitaxial growth techniques, deposition techniques or the like. The semiconductor material layers, and sacrificial layers may include any suitable materials and may have any thickness characteristics discussed herein below. The alternating layers of semiconductor material layers and sacrificial layers may be patterned into any number of fins using any suitable technique or techniques such as lithography and etch techniques. In some embodiments, the patterning includes one or more etches such to define the fin critical dimensions of the semiconductor material layers, and the formation of dummy gate and spacer structures. After patterning, the resultant semiconductor structures or nanoribbons are defined for use in a transistor structure. In some embodiments, the semiconductor material layers are silicon such as substantially monocrystalline silicon and the sacrificial layers are silicon germanium such as substantially monocrystalline silicon germanium.

FIG. 2 is a cross-sectional side view of an example integrated circuit structure 200 taken at a fin cut of a CFET structure 201 and a CFET structure 202. As shown, CFET structure 201 includes stack 203 of vertically aligned nanowires or channel material layers 204 of a first conductivity type (i.e., NMOS) and stack 205 of vertically aligned nanowires or channel material layers 206 of a second conductivity type (i.e., PMOS). Similarly, CFET structure 202 includes stack 207 of vertically aligned nanowires or channel material layers 208 of the first conductivity type (i.e., NMOS) and stack 209 of vertically aligned nanowires or channel material layers 210 of the second conductivity type (i.e., PMOS). As is shown, stack 203 of vertically aligned channel material layers 204 is vertically aligned with stack 205 of vertically aligned channel material layers 206, and stack 207 of vertically aligned channel material layers 208 is vertically aligned with stack 209 of vertically aligned channel material layers 210. Herein, the vertical or z-direction is orthogonal to an underlying substrate and in a build-up direction as is typical in the art. The horizontal or lateral direction is orthogonal to the vertical z-direction. As shown, each of channel material layers 204 of stack 203 is laterally aligned with corresponding ones of channel material layers 208 of stack 207, and each of channel material layers 206 of stack 205 is laterally aligned with corresponding ones of channel material layers 210 of stack 209.

Vertically aligned stacks 203, 207 may be separated by vertically aligned stacks 205, 209, respectively, by dielectric materials 215, 216. Dielectric materials 215, 216 may be any suitable insulating material(s) such as silicon oxide or other inorganic dielectrics such as silicon nitride, silicon oxynitride, silicon carbide, or silicon oxygen carbon. For example, dielectric materials 215, 216 may include silicon and one or more of oxygen, nitrogen, and carbon.

Furthermore, in the context of integrated circuit structure 200, CFET structure 201 and CFET structure 202 include source and drain structures that are into and out of the page with respect to the view shown herein. Such source and drain structures may be formed using any suitable technique or techniques such as epitaxial growth techniques, as is known in the art. The source and drain structures may include epitaxial nucleation layers and a bulk epitaxial material, with the source and drain structures being doped for the pertinent conductivity type. Exemplary source and drain materials include boron and/or gallium doped epitaxial silicon and germanium (SiGe) for p-type transistor structures and phosphorous and/or arsenic doped epitaxial silicon for n-type transistor structures. In some embodiments, the source and drain structures are fabricated prior to release of CFET structure 201 and CFET structure 202 channel material layers 204, 206, 208, 210 (e.g., nanowire release).

In some embodiments, CFET structure 201 and CFET structure 202 are CFET structures that have different threshold voltages. That is, CFET structure 201 and CFET structure 202 may be designed and fabricated to operate at different VTs. In integrated circuit structure 200, CFET structure 201 is a ULVT and CFET structure 202 is HVT. However, other VTs may be used. For example, CFET structure 201 may be any of ULVT, HVT, LVT, SVT, or the like, and CFET structure 202 may be another of ULVT, HVT, LVT, SVT. Furthermore, the discussed techniques and structures are not limited to two CFET structures 201, 202, but may be extended to any number and combination of CFET structures.

As shown, CFET structure 201 and CFET structure 202 may be formed over a bottom gate layer 212, and channel material layers 204, 206, 208, 210 and dielectric materials 215, 216 may be embedded in a sacrificial gate material 211. Sacrificial gate material 211 may include any suitable material that may be removed and replaced by a gate stack or gate structure, as discussed herein. In some embodiments, sacrificial gate material 211 is tungsten, however other material such as hardmask materials may be used. Bottom gate layer 212 has a top surface that defines a gate bottom 213, while a top surface of sacrificial gate material 211 (and subsequently formed gate stacks or structures) defines a gate top 214. Bottom gate layer 212 may be any suitable material and, in some embodiments, is the material of an underlying substrate. For example, the underlying substrate and/or bottom gate layer 212 may be or include a Group IV material (e.g., silicon), such as a substantially monocrystalline material.

Returning to FIG. 1, processing continues at operation 103, where a dielectric wall is formed between the laterally adjacent first and second threshold voltage CFET structures, such that the first and second threshold voltage CFET structures are embedded in a sacrificial material. The dielectric walls between the CFET structures may be formed using any suitable technique or techniques. In some embodiments, a mask is patterned over the sacrificial gate material such that openings in the mask define the pattern of the dielectric walls. Openings for the dielectric walls may then be etched and the mask removed. The openings may be filled with dielectric material using any suitable technique or techniques such as chemical vapor deposition (CVD), thermal oxidization, or others. Any overfill or overburden may be removed using planarization techniques.

FIG. 3 is a cross-sectional side view of an example integrated circuit structure 300 similar to integrated circuit structure 200, after formation of dielectric walls 301, 302, 303. As discussed, dielectric walls 301, 302, 303 may be formed using any suitable technique or techniques such as patterning a mask over sacrificial gate material 211 with openings defining dielectric walls 301, 302, 303, etching the openings, and filling dielectric walls 301, 302, 303 with any overburden being removed using planarization techniques. Dielectric walls 301, 302, 303 may be any suitable material or materials including silicon oxide, silicon nitride, silicon oxynitride, silicon carbide, or silicon oxycarbide. For example, dielectric walls 301, 302, 303 may include silicon and one or more of oxygen, nitrogen, and carbon.

Dielectric walls 301, 302, 303 extend into and out of the page (i.e., in the y-dimension) and, with bottom gate layer 212, define tubs or wells for each CFET structure 201 and CFET structure 202. As shown, dielectric walls 301, 302, 303 are high aspect ratio structures due, in part to the vertical nature of vertically aligned stacks 203, 205 of CFET structure 201 and vertically aligned stacks 207, 209 of CFET structure 202. As discussed below, when removing pertinent portions of sacrificial gate material 211 for selectively processing CFET structure 201 and CFET structure 202, dielectric walls 301, 302, 303 provide self-alignment structures. Notably, in the absence of dielectric walls 301, 302, 303 selective removal of sacrificial gate material 211 has difficulties in alignment with CFET structures 201, 202 and in vertical fidelity of the wall defined by patterning sacrificial gate material 211. Inclusion of dielectric walls 301, 302, 303 resolves these issues and offers the advantages of resultant CFETs having improved VT performance, greater structural integrity, and others.

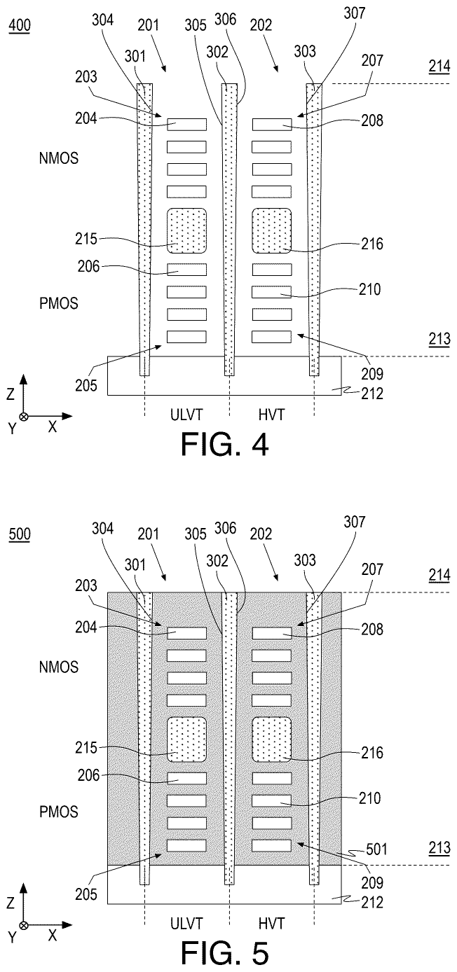

FIG. 4 is a cross-sectional side view of an example integrated circuit structure 400 similar to integrated circuit structure 300, after optional removal of sacrificial gate material 211. In some embodiments, sacrificial gate material 211 may be removed to simultaneously process CFET structure 201 and CFET structure 202 and/or to provide a more suitable sacrificial gate material for later processing. As discussed herein below, CFET structure 201 and CFET structure 202 may be selectively exposed for selective processing that is advantageous for the particular features of CFET structure 201 and CFET structure 202. However, other processing and/or features may be shared between CFET structure 201 and CFET structure 202.

FIG. 5 is a cross-sectional side view of an example integrated circuit structure 500 similar to integrated circuit structure 400, after formation of sacrificial gate material 501. Sacrificial gate material 501 may be formed using any suitable technique or techniques such as bulk deposition followed by planarization processing. In some embodiments, sacrificial gate material 501 is tungsten, however other material such as hardmask materials may be used. It is noted that the processing discussed with respect to FIGS. 4 and 5 may be bypassed in some process flows.

Returning to FIG. 1, processing continues at operation 104, where one of the first or second threshold voltage transistor structure is selectively exposed using self-aligned pinhole-based patterning and the sacrificial gate material of the selectively exposed voltage transistor structure is removed. In some embodiments, a patterned hardmask material is formed over the first and second threshold voltage transistor structures such that an opening in the patterned hardmask material is over at least a region of the first or second threshold voltage transistor structure while the other transistor structure is completely covered. In some embodiments, the patterned hardmask material includes an amorphous silicon layer directly on the sacrificial gate material and a carbon hardmask layer is on the amorphous silicon layer. However, any suitable material systems may be used. The pertinent sacrificial gate material of the selectively exposed voltage transistor structure is then removed using any suitable technique or techniques such as wet etch techniques.

Notably, due to the presence of the dielectric or pixel walls fabricated at operation 103, any lateral EPE does not impact the process flow so long as the opening is at least partially over the sacrificial gate material to be removed, and within the dielectric wall. Furthermore, any vertical edge fidelity issues are resolved due to the presence of the dielectric wall.

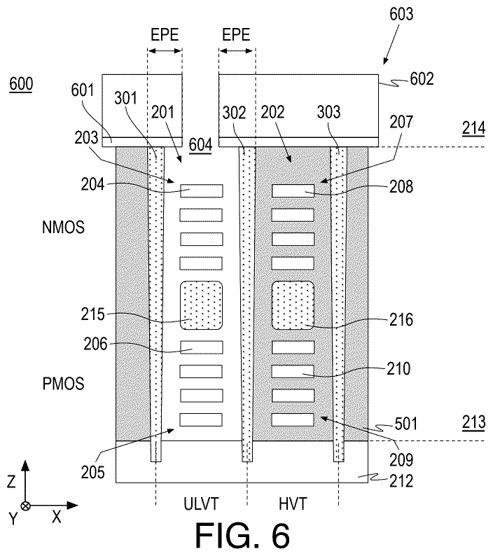

FIG. 6 is a cross-sectional side view of an example integrated circuit structure 600 similar to integrated circuit structure 500, after formation of patterned mask 603. Patterned mask 603 may include any number of layers such as first layer 601 (e.g., an amorphous silicon layer) and a second layer 602 (e.g., a carbon hardmask layer). Patterned mask 603 may be formed using any suitable technique or techniques such as bulk deposition of first layer 601 and second layer 602 followed by patterning first layer 601 and second layer 602 using a patterned resist layer (not shown), which may be subsequently removed.

As shown, an opening 604 of patterned mask 603 exposes the portions of CFET structure 201 between dielectric walls 301, 302 while the portions of CFET structure 202 between dielectric walls 302, 303 are covered. Thereby, CFET structure 201 may be selectively exposed and processed with respect to CFET structure 202. As shown, in some embodiments, sacrificial gate material 501 of CFET structure 201 is selectively removed using any suitable technique or techniques such as wet etch techniques.

As discussed, dielectric walls 302, 303 provide process latitude with respect to EPE such that opening 604 of patterned mask 603 may be skewed away from a centerline of CFET structure 201 such that, irrespective of expected process tolerance EPE, opening 604 of patterned mask 603 always lands either within and between dielectric walls 301, 302 or even partially overlapping one of dielectric walls 301, 302. It is noted that, absent dielectric walls 302, 303, such EPE provides VT shifts, and other process issues. Furthermore, the presence of dielectric walls 302, 303 provides a material interface that ensures vertical fidelity. For example, absent dielectric walls 302, 303, the etch of sacrificial gate material 501 can cause issues such as oblique patterns, bowing, edge roughness, and others.

Returning to FIG. 1, processing continues at operation 105, where the exposed transistor structure may be selectively processed using any suitable technique or techniques. For example, relative to the obscured CFET transistor structure, the exposed CFET transistor structure may be advantageously processed to selectively apply gate dielectric or dipole materials, work function metals, or the like. Furthermore, as is known in the art, the vertically separated NMOS and PMOS nanowires or channel material layers may be separately processed in a similar manner. Later, the currently obscured CFET transistor structure may be exposed and similar processing may be provided using different materials, thicknesses, process conditions, and so on. Such selective processing includes, but is not limited to, differences in gate dielectric or dipole materials, differences in work function metals, differences in material thicknesses, and selective doping. Thereby, the current techniques provide the same or addition process flexibility in fabrication of CFET transistor structures while improving patterning fidelity, process window, and transistor structures.

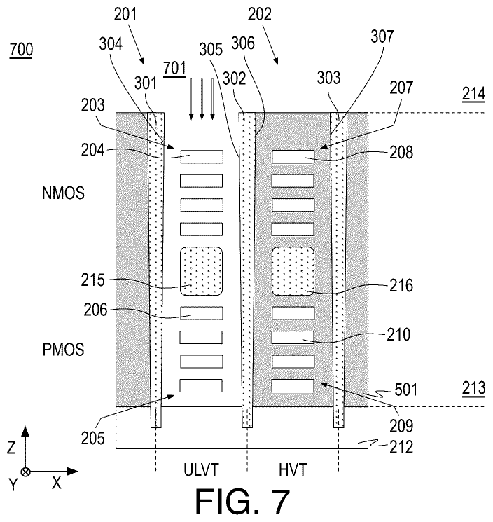

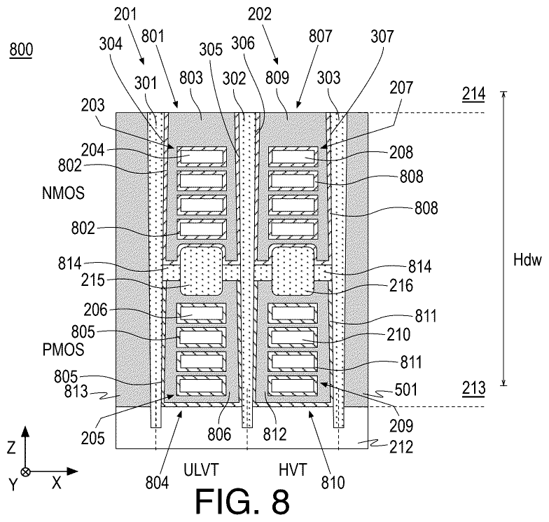

FIG. 7 is a cross-sectional side view of an example integrated circuit structure 700 similar to integrated circuit structure 600, during selective processing 701. As discussed, selective processing 701 may be any suitable processing such as application of gate dielectric or dipole materials, application of work function metals, selective doping, and so on. Furthermore, while CFET structure 201 is exposed the NMOS stack 203 of vertically aligned channel material layers 204 may be differentially processed with respect to PMOS stack 205 of vertically aligned channel material layers 206 using techniques known in the art such as applying a material to both of stacks 203, 205, application of a sacrificial material and recess to dielectric material 215, removal of the material applied to stack 203, application of a second material to stack 203, and removal of the sacrificial material. Other techniques may be deployed to provide differential materials between stacks 203, 205 for improved performance of CFET structure 201.

Returning to FIG. 1, as shown with respect to process loop 106, operations 104, 105 may be repeated any number of times for different CFET structures or threshold voltage transistor structures. With reference to FIG. 7, after selective processing 701, a sacrificial fill material may be used to embed the components of CFET structure 201. With reference to FIG. 6, a second patterned mask 603 may be used to expose CFET structure 202 while covering CFET structure 201 and the pertinent portion of sacrificial gate material 501 may be removed using, for example, wet etch techniques. Subsequently, CFET structure 202, with reference again to FIG. 7 may then be selectively processed to provide any suitable gate dielectric or dipole materials, differences in work function metals, differences in material thicknesses, and selective doping, as discussed with respect to CFET structure 201.

Processing continues at operation 107, where, after selective processing of the transistor structures, any shared processing of the gate structure components is performed. Such processing may include forming bulk gate materials, for example. Such processing may be performed by patterning, exposing transistor structure components, material deposition, and planarization, or other similar processes in analogy to those discussed with respect to operations 104, 105.

FIG. 8 is a cross-sectional side view of an example integrated circuit structure 800 similar to integrated circuit structure 700, after selective processing of each of CFET structure 201 and CFET structure 202. As shown, CFET structure 201 includes one or more of a gate dielectric, gate dipole material, or gate work function material layer 802 on each of channel material layers 204. As shown, material layer 802 is also on a sidewall or surface 304 of dielectric wall 301 and a sidewall or surface 305 of dielectric wall 302. In the context of integrated circuit structure 800, material layer 802 as well as material layers 805, 808, and 811 are illustrated as a single layer, but may include a bilayer, trilayer, or the like depending on the architecture of integrated circuit structure 800. CFET structure 201 includes a gate electrode 803 on material layer 802, and material layer 802 and gate electrode 803 may be characterized as a gate stack or gate structure 801.

CFET structure 201 further includes a gate dielectric, gate dipole material, or gate work function material layer 805 on each of channel material layers 206, and a gate electrode 806 on material layer 805. Material layer 805 is also on sidewall or surface 304 of dielectric wall 301 and sidewall or surface 305 of dielectric wall 302. Material layer 805 and gate electrode 806 may be characterized as a gate stack or gate structure 804. As shown, material layer 802 and gate electrode 803 may be separated from material layer 805 and gate electrode 806 by a dielectric material 814. Dielectric material 814 may be any suitable insulative material(s) including silicon oxide, silicon nitride, silicon oxynitride, silicon carbide, or silicon oxygen carbon. For example, dielectric material 814 may include silicon and one or more of oxygen, nitrogen, and carbon.

Similarly, CFET structure 202 includes a gate dielectric, gate dipole material, or gate work function material layer 808 on each of channel material layers 208, and a gate electrode 809 on material layer 808. Material layer 808 is also on a sidewall or surface 306 of dielectric wall 302 and a sidewall or surface 307 of dielectric wall 303. Notably, sidewall or surface 306 is an opposing sidewall of sidewall or surface 305 of dielectric wall 302. Material layer 808 and gate electrode 809 may be characterized as a gate stack or gate structure 807. CFET structure 202 further includes a gate dielectric, gate dipole material, or gate work function material layer 811 on each of channel material layers 210, and a gate electrode 812 on material layer 811. Material layer 811 is also on sidewall or surface 306 of dielectric wall 302 and sidewall or surface 307 of dielectric wall 303. Material layer 811 and gate electrode 812 may be characterized as a gate stack or gate structure 810. As shown, material layer 808 and gate electrode 809 may be separated from material layer 811 and gate electrode 813 by dielectric material 814.

In some embodiments, one or more of material layers 802, 805, 808, and 811 includes a gate dielectric or dipole layer such as aluminum oxide, hafnium oxide, zirconium oxide, titanium silicon oxide, hafnium silicon oxide, or silicon nitride. For example, material layers 802, 805, 808, and 811 may include aluminum and oxygen; hafnium and oxygen; zirconium and oxygen; titanium, silicon, and oxygen; hafnium, silicon, and oxygen; or silicon and nitrogen. In addition or in the alternative, one or more of material layers 802, 805, 808, and 811 includes a work function layer of platinum, nickel, titanium nitride, or tantalum nitride. Gate electrodes 803, 806, 809, 812 may be any suitable fill material such as tungsten. However, other material systems may be used. Notably, material layers 802, 805, 808, and 811 may be the same or they may be different materials, stacks, thicknesses, etc. to optimize CFET structures 201, 202.

As shown, integrated circuit structure 800 includes CFET structure 201 having stack 203 of vertically aligned channel material layers 204, stack 205 of vertically aligned channel material layers 206 complementary to and vertically aligned with stack 203 of vertically aligned channel material layers 204. A first gate stack is coupled to at least stack 203 of vertically aligned channel material layers 204. Integrated circuit structure 800 further includes CFET structure 202 having stack 207 of vertically aligned channel material layers 208, stack 209 of vertically aligned channel material layers 210 complementary to and vertically aligned with stack 207 of vertically aligned channel material layers 208. A second gate stack is coupled to at least stack 209 of vertically aligned channel material layers 210. Dielectric wall 302 is between CFET structure 201 and CFET structure 202 such that the first gate stack is on surface 305 of dielectric wall 302 and the second gate stack is on an opposing surface 306 of dielectric wall 302. Dielectric wall 301 is opposite CFET structure 201 from dielectric wall 302. Bottom gate layer 212 extends under dielectric walls 301, 302, 303, CFET structures 201, 202, and the walls 301, 302, 303 have a common height (Hdw) from bottom gate layer 212.

FIG. 8 illustrates an exemplary gate contact architecture for CFET structures 201, 202. However, other architectures are available. FIG. 9 is a cross-sectional side view of an example integrated circuit structure 900 similar to integrated circuit structure 800, with a single gate electrode 901 coupled to channel material layers 204 and channel material layers 206. In the context of integrated circuit structure 900, gate electrode 901 extends along the entire common height (Hdw) of dielectric walls 301, 302. Although illustrated with respect to CFET structure 201 having single gate electrode 901, either or both of CFET structures 201, 202 may have a common gate electrode within the tub architecture of integrated circuit structure 900.

Returning to FIG. 1, processing continues at operation 108, where frontside contacts, frontside metallization, and optional backside metallization are formed, and the resultant device is output. For example, any or all of the discussed source structures, drain structures, and gate structures the transistor structures may be contacted by frontside metal contacts using any suitable technique or techniques such as patterning and metal deposition processing as is known in the art. The frontside contacts are then interconnected by metallization layers over the frontside contact. Backside metallization is optionally fabricated opposite the frontside metallization with respect to a device layer including the discussed integrated circuit structures. In some embodiments, the frontside metallization provides signal routing and the backside metallization to provides power delivery. However, any interconnect routing may be used. Additional fabrication processes may then be completed, and the resultant structure may be output. Such processing may include backend processing, dicing, packaging, assembly, and so on. The resultant device (e.g., integrated circuit die) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

FIG. 10 is a cross-sectional side view of a multi-layer integrated circuit device structure 1000 incorporating CFET integrated circuit structure 800 and CFET integrated circuit structure 900, arranged in accordance with at least some embodiments of the present disclosure. Although illustrated and discussed with respect to CFET integrated circuit structure 800 and CFET integrated circuit structure 900, any integrated circuit structures discussed herein may be deployed in the context of multi-layer integrated circuit device structure 1000. As shown, multi-layer integrated circuit device structure 1000 is incorporated in integrated circuit (IC) die 1007 such that multi-layer integrated circuit device structure 1000 includes frontside metallization layers 1001 (or frontside interconnect layers) and backside metallization layers 1002 (or backside interconnect layers). Frontside metallization layers 1001 and backside metallization layers 1002 may be formed using any suitable technique or techniques such as dual damascene techniques, single damascene techniques, subtractive metallization patterning techniques, or the like. In some embodiments, backside metallization layers 1002 are not deployed.

In some embodiments, interconnectivity, signal routing, power-delivery, and the like may be provided by frontside metallization layers 1001. Adjacent metallization layers, such as metallization interconnects 1009, are interconnected by vias, such as vias 1003, that may be characterized as part of the metallization layers or between the metallization layers. As shown, in some embodiments, frontside metallization layers 1001 are formed over and immediately adjacent CFET integrated circuit structure 800 and CFET integrated circuit structure 900. In the illustrated example, frontside metallization layers 1001 include M0, V0, M1, M2/V1, M3/V2, and M4/V3. However, frontside metallization layers 1001 may include any number of metallization layers such as six, eight, or more metallization layers.

Similarly, backside metallization layers 1002, may be used for interconnectivity, signal routing, power-delivery, and any other suitable electrical connectivity. In some embodiments, frontside metallization layers 1001 are used exclusively for signal routing and backside metallization layers 1002 are used exclusively for power delivery. However, any interconnection architecture may be used. In the illustrated example, package level interconnects 1008 are provided on or over a device backside as bumps over a passivation layer 1005. However, package level interconnects 1008 may be provided using any suitable interconnect structures such as bond pads, solder bumps, etc. As shown, in some embodiments, backside metallization layers 1002 are formed over and immediately adjacent CFET integrated circuit structure 800 and CFET integrated circuit structure 900 such that a device layer 1004 including CFET integrated circuit structure 800 and CFET integrated circuit structure 900 is between frontside metallization layers 1001 and backside metallization layers 1002. In the illustrated example, backside metallization layers 1002 include BM0, BM1, and BM2 with intervening via layers. However, backside metallization layers 1002 may include any number of metallization layers such as three, four, or more metallization layers.

In some embodiments, an integrated circuit structure including CFET integrated circuit structure 800 and/or CFET integrated circuit structure 900 is deployed in a monolithic integrated circuit (IC) die 1007 including gate-all-around field effect transistor structures (e.g., GAA-CFETs) including any of the discussed components and characteristics. As shown, a power supply 1006 may be coupled to IC die 1007, such that power supply 1006 may include a battery, voltage converter, power supply circuitry, or the like.

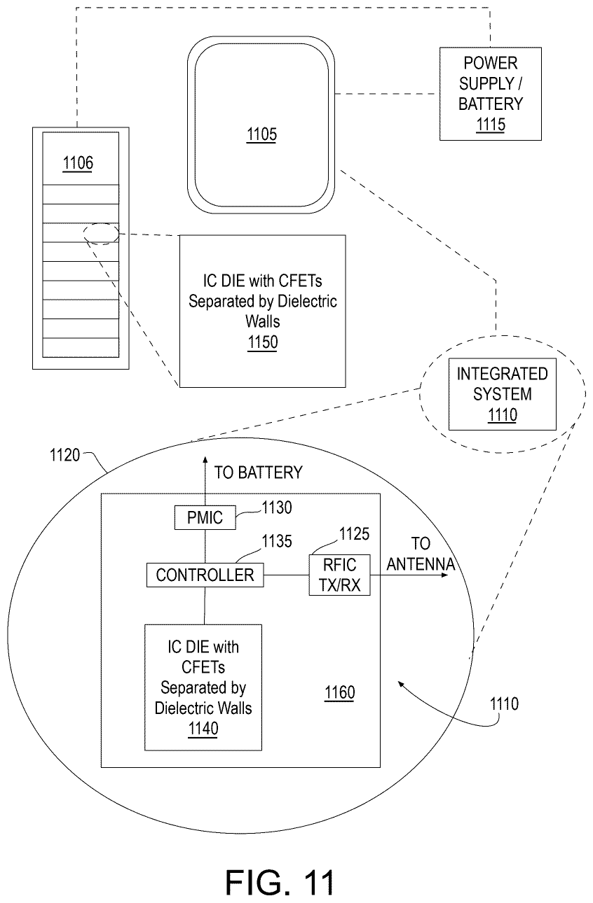

FIG. 11 illustrates exemplary systems employing CFET integrated circuit structures with transistor structures separated by dielectric walls, in accordance with some embodiments. The system may be a mobile computing platform 1105 and/or a data server machine 1106, for example. Either may employ a component assembly including an IC die having CFET integrated circuit structures with transistor structures separated by dielectric walls as described elsewhere herein. Server machine 1106 may be any commercial server, for example including any number of high-performance computing platforms disposed within a rack and networked together for electronic data processing, which in the exemplary embodiment includes an IC die assembly 1150 with an IC die employing integrated circuit structures with CFET integrated circuit structures having transistor structures separated by dielectric walls as described elsewhere herein. Mobile computing platform 1105 may be any portable device configured for each of electronic data display, electronic data processing, wireless electronic data transmission, or the like. For example, mobile computing platform 1105 may be any of a tablet, a smart phone, a laptop computer, etc., and may include a display screen (e.g., a capacitive, inductive, resistive, or optical touchscreen), a chip-level or package-level integrated system 1110, and a battery 1115. Although illustrated with respect to mobile computing platform 1105, in other examples, chip-level or package-level integrated system 1110 and a battery 1115 may be implemented in a desktop computing platform, an automotive computing platform, an internet of things platform, or the like. As discussed below, in some examples, the disclosed systems may include a sub-system 1160 such as a system on a chip (SOC) or an integrated system of multiple ICs, which is illustrated with respect to mobile computing platform 1105.

Whether disposed within integrated system 1110 illustrated in expanded view 1120 or as a stand-alone packaged device within data server machine 1106, sub-system 1160 may include memory circuitry and/or processor circuitry 1140 (e.g., RAM, a microprocessor, a multi-core microprocessor, graphics processor, etc.), a power management integrated circuit (PMIC) 1130, a controller 1135, and a radio frequency integrated circuit (RFIC) 1125 (e.g., including a wideband RF transmitter and/or receiver (TX/RX)). As shown, one or more IC dies, such as memory circuitry and/or processor circuitry 1140 may be fabricated and implemented such that one or more have an IC die employing CFET integrated circuit structures with transistor structures separated by dielectric walls as described herein. In some embodiments, RFIC 1125 includes a digital baseband and an analog front end module further comprising a power amplifier on a transmit path and a low noise amplifier on a receive path). Functionally, PMIC 1130 may perform battery power regulation, DC-to-DC conversion, etc., and so has an input coupled to battery 1115, and an output providing a current supply to other functional modules. As further illustrated in FIG. 11, in the exemplary embodiment, RFIC 1125 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1140 may provide memory functionality for sub-system 1160, high level control, data processing and the like for sub-system 1160. In alternative implementations, each of the SOC modules may be integrated onto separate ICs coupled to a package substrate, interposer, or board.

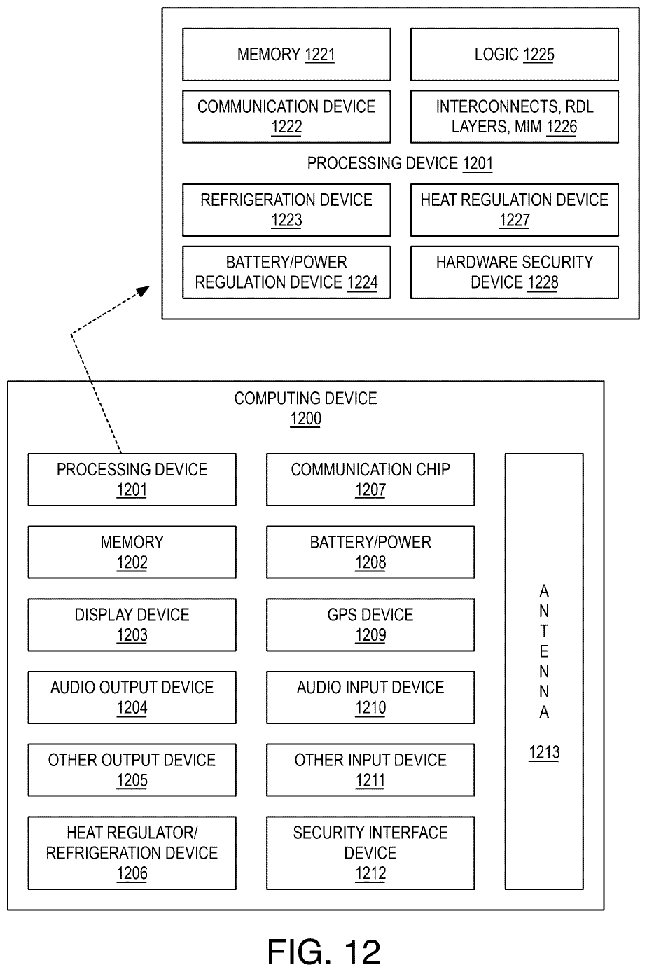

FIG. 12 is a block diagram of a computing device 1200, in accordance with some embodiments. For example, one or more components of computing device 1200 may include any of the CFET integrated circuit structures with transistor structures separated by dielectric walls as discussed elsewhere herein. A number of components are illustrated in FIG. 12, but any one or more of these components may be omitted or duplicated, as suitable for the application. In some embodiments, some of the components included in computing device 1200 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Any of such packaged components may include CFET integrated circuit structures with transistor structures separated by dielectric walls as discussed herein. Additionally, in various embodiments, computing device 1200 may not include one or more of the components illustrated in FIG. 12, but computing device 1200 may include interface circuitry for coupling to the one or more components. For example, computing device 1200 may not include a display device 1203, but may include display device interface circuitry (e.g., a connector and driver circuitry) to which display device 1203 may be coupled.

Computing device 1200 may include a processing device 1201 (e.g., one or more processing devices). As used herein, the term processing device or processor indicates a device that processes electronic data from registers and/or memory to transform that electronic data into other electronic data that may be stored in registers and/or memory. Processing device 1201 may include a memory 1221, a communication device 1222, a refrigeration/active cooling device 1223, a battery/power regulation device 1224, logic 1225, interconnects 1226, a heat regulation device 1227, and a hardware security device 1228.

Processing device 1201 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable compute units.

Processing device 1201 may include a memory 1202, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 1201 shares a package with memory 1202. This memory may be used as cache memory and may include embedded dynamic random-access memory (eDRAM) or spin transfer torque magnetic random-access memory (STT-M RAM).

Computing device 1200 may include a heat regulation/refrigeration device 1206. Heat regulation/refrigeration device 1206 may maintain processing device 1201 (and/or other components of computing device 1200) at a predetermined low temperature during operation. This predetermined low temperature may be any temperature discussed elsewhere herein.

In some embodiments, computing device 1200 may include a communication chip 1207 (e.g., one or more communication chips). For example, the communication chip 1207 may be configured for managing wireless communications for the transfer of data to and from computing device 1200. The term “wireless” and its derivatives may be used to describe circuits, devices, systems, methods, techniques, communications channels, etc., that may communicate data through the use of modulated electromagnetic radiation through a nonsolid medium.

Computing device 1200 may include any photonics structure discussed herein that may facilitate communication between one or more instances of processing device 1201 and/or one or more instances of memory 1202, for example.

Computing device 1200 may include battery/power circuitry 1208. Battery/power circuitry 1208 may include one or more energy storage devices (e.g., batteries or capacitors) and/or circuitry for coupling components of computing device 1200 to an energy source separate from computing device 1200 (e.g., AC line power).

Computing device 1200 may include a display device 1203 (or corresponding interface circuitry, as discussed above). Display device 1203 may include any visual indicators, such as a heads-up display, a computer monitor, a projector, a touchscreen display, a liquid crystal display (LCD), a light-emitting diode display, or a flat panel display, for example.

Computing device 1200 may include an audio output device 1204 (or corresponding interface circuitry, as discussed above). Audio output device 1204 may include any device that generates an audible indicator, such as speakers, headsets, or earbuds, for example.

Computing device 1200 may include an audio input device 1210 (or corresponding interface circuitry, as discussed above). Audio input device 1210 may include any device that generates a signal representative of a sound, such as microphones, microphone arrays, or digital instruments (e.g., instruments having a musical instrument digital interface (MIDI) output).

Computing device 1200 may include a global positioning system (GPS) device 1209 (or corresponding interface circuitry, as discussed above). GPS device 1209 may be in communication with a satellite-based system and may receive a location of computing device 1200, as known in the art.

Computing device 1200 may include another output device 1205 (or corresponding interface circuitry, as discussed above). Examples include an audio codec, a video codec, a printer, a wired or wireless transmitter for providing information to other devices, or an additional storage device.

Computing device 1200 may include another input device 1211 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1200 may include a security interface device 1212. Security interface device 1212 may include any device that provides security measures for computing device 1200 such as intrusion detection, biometric validation, security encode or decode, managing access lists, malware detection, or spyware detection.

Computing device 1200 may include an antenna 1213. Antenna 1213 may include any device that translates electrical current to radio waves and/or translates radio waves to electrical current.

Computing device 1200, or a subset of its components, may have any appropriate form factor, such as a server or other networked computing component, a mobile device, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a first transistor structure comprising a first stack of channel material layers, a second stack of channel material layers complementary to the first stack of channel material layers vertically aligned with the first stack of material layers, and a first gate stack coupled to at least the first stack of channel material layers, a second transistor structure comprising a third stack of channel material layers, a fourth stack of channel material layers complementary to the third stack of material layers vertically aligned with the first stack of material layers, and a second gate stack coupled to at least the third stack of channel material layers, wherein the third stack of channel material layers is laterally aligned with the first stack of channel material layers, and the fourth stack of channel material layers is laterally aligned with the second stack of channel material layers, and a dielectric wall between the first transistor structure and the second transistor structure, wherein the first gate stack is on a first surface of the dielectric wall and the second gate stack is on an opposing second surface of the dielectric wall.

In one or more second embodiments, further to the first embodiments, the apparatus further comprises a second dielectric wall opposite the first transistor structure from the dielectric wall, and a bottom gate layer extending under the dielectric wall, the first transistor structure, and the second dielectric wall, wherein the dielectric wall and the second dielectric wall have a common height from the bottom gate layer.

In one or more third embodiments, further to the first or second embodiments, the first gate stack comprises a first work function metal or dipole material on the first stack of channel material layers and on the dielectric wall, and the apparatus further comprises a second work function metal or second dipole material coupled to the second stack of channel material layers and on the first surface of the dielectric wall.

In one or more fourth embodiments, further to the first through third embodiments, the second gate stack comprises a third work function metal or dipole material on the third stack of channel material layers and on the second surface of the dielectric wall, and the apparatus further comprises a fourth work function metal or fourth dipole material coupled to the fourth stack of channel material layers and on the second surface of the dielectric wall.

In one or more fifth embodiments, further to the first through fourth embodiments, a gate metal of the first gate stack is coupled to the second stack of channel material layers, and the first gate stack extends along an entire height of the dielectric wall.

In one or more sixth embodiments, further to the first through fifth embodiments, the dielectric wall comprises silicon and one of oxygen or nitrogen.

In one or more seventh embodiments, further to the first through sixth embodiments, the apparatus further comprises a dielectric material vertically between the first stack of channel material layers and the second stack of channel material layers.

In one or more eighth embodiments, further to the first through seventh embodiments, the apparatus further comprises a power supply, and an integrated circuit device coupled to the power supply, the integrated circuit device comprising the first transistor structure, the second transistor structure, and the dielectric wall.

In one or more ninth embodiments, a system comprises an IC die according to any of the apparatuses of the first through eighth embodiments, the system further including a power supply or a display coupled to one of first or second transistor structures.

In one or more tenth embodiments, an apparatus comprises a first stack of nanowires and a second stack of nanowires complementary to the first stack of nanowires vertically aligned with the first stack of nanowires, a first gate structure coupled to at least the first stack of nanowires, a third stack of nanowires and a fourth stack of nanowires complementary to the third stack of nanowires vertically aligned with the third stack of nanowires, a second gate structure coupled to at least the third stack of nanowires, wherein the third stack of nanowires is laterally aligned with the first stack of nanowires, and the fourth stack of nanowires is laterally aligned with the second stack of nanowires, and a dielectric wall laterally between the first stack of nanowires and the third stack of nanowires and laterally between the second stack of nanowires and the fourth stack of nanowires, wherein the first gate structure is on a first surface of the dielectric wall and the second gate structure is on an opposing second surface of the dielectric wall.

In one or more eleventh embodiments, further to the tenth embodiments, the apparatus further comprises a second dielectric wall opposite the first stack of nanowires from the dielectric wall, and a bottom gate layer extending under the dielectric wall, the first stack of nanowires, and the second dielectric wall, wherein the dielectric wall and the second dielectric wall have a common height from the bottom gate layer.

In one or more twelfth embodiments, further to the tenth or eleventh embodiments, the first gate structure comprises a first work function metal or dipole material on the first stack of nanowires and on the dielectric wall, and the apparatus further comprises second work function metal or second dipole material coupled to the second stack of nanowires and on the first surface of the dielectric wall.

In one or more thirteenth embodiments, further to the tenth through twelfth embodiments, the second gate structure comprises a third work function metal or dipole material on the third stack of nanowires and on the second surface of the dielectric wall, and the apparatus further comprises a fourth work function metal or fourth dipole material coupled to the fourth stack of nanowires and on the second surface of the dielectric wall.

In one or more fourteenth embodiments, further to the tenth through thirteenth embodiments, the dielectric wall comprises silicon and one of oxygen or nitrogen.

In one or more fifteenth embodiments, further to the tenth through fourteenth embodiments, the apparatus further comprises a dielectric material vertically between the first stack of nanowires and the second stack of nanowires.

In one or more sixteenth embodiments, further to the tenth through fifteenth embodiments, the apparatus further comprises a power supply, and an integrated circuit device coupled to the power supply, the integrated circuit device comprising the first stack of nanowires, the second stack of nanowires, and the dielectric wall.

In one or more seventeenth embodiments, a system comprises an IC die according to any of the apparatuses of the tenth through sixteenth embodiments, the system further including a power supply or a display coupled to one of first or second stack of nanowires.

In one or more eighteenth embodiments, a method comprises forming a mask comprising an opening over a first transistor structure comprising a first stack of channel material layers, a second stack of channel material layers complementary to the first stack of channel material layers vertically aligned with the first stack of material layers, and a first sacrificial material surrounding the first stack of channel material layers and the second stack of channel material layers, the mask covering a second transistor structure comprising a third stack of channel material layers, a fourth stack of channel material layers complementary to the third stack of channel material layers vertically aligned with the first stack of material layers, and a second sacrificial material surrounding the third stack of channel material layers and the fourth stack of channel material layers, wherein a dielectric wall is between the first sacrificial material and the second sacrificial material, selectively removing the first sacrificial material to expose the first stack of channel material layers and the second stack of channel material layers, and forming at least portion of a first gate structure on the first stack of channel material layers or the second stack of channel material layers.

In one or more nineteenth embodiments, further to the eighteenth embodiments, the method further comprises forming a second mask comprising a second opening over the second transistor structure.

In one or more twentieth embodiments, further to the eighteenth or nineteenth embodiments, the method further comprises selectively removing the second sacrificial material to expose the third stack of channel material layers and the fourth stack of channel material layers, and forming at least portion of a second gate structure on the third stack of channel material layers or the fourth stack of channel material layers.

In one or more twenty-first embodiments, further to the eighteenth through twentieth embodiments, the dielectric wall comprises silicon and one of oxygen or nitrogen, and the first sacrificial material and the second sacrificial material each comprise tungsten.

In one or more twenty-second embodiments, further to the eighteenth through twenty-first embodiments, at least a portion of the opening is over the dielectric wall.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a first transistor structure comprising a first stack of channel material layers, a second stack of channel material layers complementary to the first stack of channel material layers vertically aligned with the first stack of material layers, and a first gate stack coupled to at least the first stack of channel material layers;
a second transistor structure comprising a third stack of channel material layers, a fourth stack of channel material layers complementary to the third stack of material layers vertically aligned with the first stack of material layers, and a second gate stack coupled to at least the third stack of channel material layers, wherein the third stack of channel material layers is laterally aligned with the first stack of channel material layers, and the fourth stack of channel material layers is laterally aligned with the second stack of channel material layers; and
a dielectric wall between the first transistor structure and the second transistor structure, wherein the first gate stack is on a first surface of the dielectric wall and the second gate stack is on an opposing second surface of the dielectric wall.

2. The apparatus of claim 1, further comprising:
a second dielectric wall opposite the first transistor structure from the dielectric wall; and
a bottom gate layer extending under the dielectric wall, the first transistor structure, and the second dielectric wall, wherein the dielectric wall and the second dielectric wall have a common height from the bottom gate layer.

3. The apparatus of claim 1, wherein the first gate stack comprises a first work function metal or dipole material on the first stack of channel material layers and on the dielectric wall, the apparatus further comprising:
a second work function metal or second dipole material coupled to the second stack of channel material layers and on the first surface of the dielectric wall.

4. The apparatus of claim 3, wherein the second gate stack comprises a third work function metal or dipole material on the third stack of channel material layers and on the second surface of the dielectric wall, the apparatus further comprising:
a fourth work function metal or fourth dipole material coupled to the fourth stack of channel material layers and on the second surface of the dielectric wall.

5. The apparatus of claim 1, wherein a gate metal of the first gate stack is coupled to the second stack of channel material layers, and the first gate stack extends along an entire height of the dielectric wall.

6. The apparatus of claim 1, wherein the dielectric wall comprises silicon and one of oxygen or nitrogen.

7. The apparatus of claim 1, further comprising:
a dielectric material vertically between the first stack of channel material layers and the second stack of channel material layers.

8. The apparatus of claim 1, further comprising:
a power supply; and
an integrated circuit device coupled to the power supply, the integrated circuit device comprising the first transistor structure, the second transistor structure, and the dielectric wall.

9. An apparatus, comprising:
a first stack of nanowires and a second stack of nanowires complementary to the first stack of nanowires vertically aligned with the first stack of nanowires;
a first gate structure coupled to at least the first stack of nanowires;
a third stack of nanowires and a fourth stack of nanowires complementary to the third stack of nanowires vertically aligned with the third stack of nanowires;
a second gate structure coupled to at least the third stack of nanowires, wherein the third stack of nanowires is laterally aligned with the first stack of nanowires, and the fourth stack of nanowires is laterally aligned with the second stack of nanowires; and
a dielectric wall laterally between the first stack of nanowires and the third stack of nanowires and laterally between the second stack of nanowires and the fourth stack of nanowires, wherein the first gate structure is on a first surface of the dielectric wall and the second gate structure is on an opposing second surface of the dielectric wall.

10. The apparatus of claim 9, further comprising:
a second dielectric wall opposite the first stack of nanowires from the dielectric wall; and
a bottom gate layer extending under the dielectric wall, the first stack of nanowires, and the second dielectric wall, wherein the dielectric wall and the second dielectric wall have a common height from the bottom gate layer.

11. The apparatus of claim 9, wherein the first gate structure comprises a first work function metal or dipole material on the first stack of nanowires and on the dielectric wall, the apparatus further comprising:
a second work function metal or second dipole material coupled to the second stack of nanowires and on the first surface of the dielectric wall.

12. The apparatus of claim 11, wherein the second gate structure comprises a third work function metal or dipole material on the third stack of nanowires and on the second surface of the dielectric wall, the apparatus further comprising:
a fourth work function metal or fourth dipole material coupled to the fourth stack of nanowires and on the second surface of the dielectric wall.

13. The apparatus of claim 9, wherein the dielectric wall comprises silicon and one of oxygen or nitrogen.

14. The apparatus of claim 9, further comprising:
a dielectric material vertically between the first stack of nanowires and the second stack of nanowires.

15. The apparatus of claim 9, further comprising:
a power supply; and
an integrated circuit device coupled to the power supply, the integrated circuit device comprising the first stack of nanowires, the second stack of nanowires, and the dielectric wall.

16. A method, comprising:
forming a mask comprising an opening over a first transistor structure comprising a first stack of channel material layers, a second stack of channel material layers complementary to the first stack of channel material layers vertically aligned with the first stack of material layers, and a first sacrificial material surrounding the first stack of channel material layers and the second stack of channel material layers, the mask covering a second transistor structure comprising a third stack of channel material layers, a fourth stack of channel material layers complementary to the third stack of channel material layers vertically aligned with the first stack of material layers, and a second sacrificial material surrounding the third stack of channel material layers and the fourth stack of channel material layers, wherein a dielectric wall is between the first sacrificial material and the second sacrificial material;
selectively removing the first sacrificial material to expose the first stack of channel material layers and the second stack of channel material layers; and
forming at least portion of a first gate structure on the first stack of channel material layers or the second stack of channel material layers.

17. The method of claim 16, further comprising:
forming a second mask comprising a second opening over the second transistor structure.

18. The method of claim 17, further comprising:
selectively removing the second sacrificial material to expose the third stack of channel material layers and the fourth stack of channel material layers; and
forming at least portion of a second gate structure on the third stack of channel material layers or the fourth stack of channel material layers.

19. The method of claim 16, wherein the dielectric wall comprises silicon and one of oxygen or nitrogen, and the first sacrificial material and the second sacrificial material each comprise tungsten.

20. The method of claim 16, wherein at least a portion of the opening is over the dielectric wall.
